(19) United States
(12) Patent Application Publication
(10) Pub. No.: US 2015/0070094 A1
(43) Pub. Date: Mar. 12, 2015

(54) DOHERTY POWER AMPLIFIER WITH COUPLING MECHANISM INDEPENDENT OF DEVICE RATIOS

(71) Applicant: Telefonaktiebolaget LM Ericsson (Publ), Stockholm (SE)

(72) Inventor: Bi Pham, Ottowa (CA)

(73) Assignee: Telefonaktiebolaget LM Ericsson (Publ), Stockholm (SE)

(21) Appl. No.: 14/022,416

(22) Filed: Sep. 10, 2013

(51) Int. Cl. H03F 3/21

(52) U.S. Cl. CPC H03F 3/211; H03F 2203/21139; H03F 2200/423
USPC 330/295

(57) ABSTRACT

A method and system for design and implementation of symmetric and asymmetric Doherty power amplifiers are disclosed. Quarter wave transmission lines are interposed between the main and peak power amplifiers of a Doherty power amplifier system and a 3 dB hybrid coupler. The impedances of the quarter wavelength transmission lines are chosen based on a ratio of the power ratings of the main and peak power amplifiers such that the impedances seen by the main and peak power amplifiers is independent of the impedance of the 3 dB coupler.

### TECHNICAL FIELD

The present invention relates to wide band amplifiers, and in particular to Doherty amplifier output circuitry for wide band applications.

### BACKGROUND

Complex modulation schemes are used in wireless communication systems to improve the spectral efficiency of the output signals. These signals have high peak to average power ratio, which requires power amplifiers to operate further away from the nonlinear region where the amplifier is least efficient. Operating in the less efficient region increases operating temperature and increases power consumption. To increase efficiency of the amplifier, a Doherty amplifier configuration is usually employed along with a feed forward and/or feedback system which enables the amplifier to operate closer to the saturation region, thereby achieving higher efficiency. FIG. 1 is a simplified diagram of a conventional Doherty amplifier 2. The Doherty amplifier 2 includes a main amplifier 4 and a peak amplifier 6. The main amplifier 4 is connected to a first impedance 8 and the peak amplifier 6 is connected to a T-junction which is connected to the first impedance 8 and a second impedance 10. The load impedance 12 is connected to the output impedance of the Doherty amplifier 2.

A conventional Doherty power amplifier operates at high efficiency by only turning on the peak amplifier 6 whenever the input signal peaks. FIG. 2 is a graph of the current of the main amplifier, curve 17, the current of the peak amplifier, curve 18, and the overall efficiency of the Doherty amplifier, curve 19. As can be seen, current flow in the main amplifier reaches a saturation point at backoff power, above which the peak amplifier current increases from zero to maximum current. The current generated from the load of the peak amplifier 6 modulates the output load of the main amplifier 4, keeping the voltage swing high and keeping the device operating in the high-efficiency region. When the Doherty amplifier 2 operates at full power, the main amplifier 4 sees an optimal impedance of Rload 12. When the Doherty amplifier operates at backoff power—that is, when the peak amplifier is off—the main amplifier 4 sees an impedance of twice the load impedance 12. The variation in load impedance associated with full power and backoff power operation improves the overall efficiency of the Doherty amplifier 2.

The T junction based topology, as shown in FIG. 1, suffers from a narrow bandwidth which makes it unsuitable for wideband and multiband applications such as in modern wireless communication systems. The narrow bandwidth of the Doherty amplifier is mainly a result of use of quarter wave transmission lines 8 and 10. As the optimal load for the power amplifier is a very low impedance, a matching network is required to transform from a low impedance to the load impedance of 50 ohms. Another contribution to narrow band performance is an off-state high impedance transformer at the output of the peak device 6.

Another topology that has been proposed uses a hybrid or branch coupler instead of a T junction as a combiner. This is shown in FIG. 3, where the main power amplifier 4 and the peak amplifier 6 are electrically connected to the input ports of a coupler 16. Instead of terminating the isolation port of the coupler 16, the isolation port can be left as an open or short. This technique allows the coupler to provide the same load modulation effect as a conventional Doherty amplifier. A main advantage of this technique is that it has a broadband characteristic which is suitable for multiband applications. The hybrid coupler of FIG. 3 is shown in FIG. 4. Port P1 is used for the main amplifier input, port P4 is left as an open circuit, port P3 is the output and port P2 is used for the peak amplifier input. Although a hybrid coupler is useful for a symmetrical Doherty amplifier, the, use of a hybrid coupler presents difficulties when using asymmetric amplifiers because the hybrid coupler must be especially designed to account for the mismatch in impedance due to asymmetry in power between the peak and main amplifiers.

Thus, another approach to increase the overall efficiency of the Doherty power amplifier is to use a power amplifier for the main amplification that has a lower power rating than the power rating of a power amplifier used for the peak amplification. This type of Doherty power amplifier is called asymmetric and is sometimes preferred over a conventional symmetric two-way Doherty power amplifier, where the power ratings of the main and peak power amplifiers are the same. However, the asymmetric Doherty power amplifier requires a customized asymmetric hybrid coupler, as opposed to use of a standard 3 dB hybrid coupler for the symmetric Doherty amplifier. Use of a customized asymmetric hybrid coupler increases cost and design time and presents design difficulties.

### SUMMARY

Methods and systems for design and implementation of symmetric and asymmetric Doherty power amplifiers are disclosed. According to one aspect, the invention provides a power amplifier system that includes a first power amplifier having a first power amplifier output and a second power amplifier having a second power amplifier output. A first quarter wave length transmission line has an input connected to the first power amplifier output of the first power amplifier. The first quarter wave length transmission line has a first transmission line output and a first transmission line impedance. A second quarter wave length transmission line has an input connected to the second power amplifier output of the second power amplifier. The second quarter wave length transmission line has a second transmission line output and a second transmission line impedance. A symmetric coupling mechanism having a coupling mechanism impedance has a first input connected to the first transmission line output of the first quarter wave length transmission line and has a second input connected to the second transmission line output of the second quarter wave length transmission line. The first and second transmission line impedances are chosen based on a difference in power ratings of the first power amplifier and the second power amplifier.

According to this aspect, in some embodiments, a third impedance is observed by the first power amplifier that is independent of the coupling mechanism impedance. In some embodiments, a third impedance observed by the second power amplifier is independent of the coupling mechanism impedance. The coupling mechanism impedance may be a function of a ratio of a current in the second transmission line to a current in the first transmission line. In some embodiments, the coupling mechanism impedance, Rₘ, is given by:

$${R}_{m} = ( 2 - \frac{{I}_{p}}{{I}_{m}} ) \cdot {Z}_{o}$$

where Iₚ is a current in the second amplifier, Iₘ is a current in the first amplifier and Zₒ is a load impedance driven by the power amplifier system. In some embodiments, a third impedance, Z_{mainback}, observed by the first power amplifier operating in a backoff power region, is given by:

$${Z}_{mainback} = \frac{{Z}_{om}^{2}}{2 \cdot {Z}_{o}}$$

where Zₒₘ is the first transmission line characteristic impedance and Zₒ is a load impedance driven by the power amplifier system. In some embodiments, a third impedance, Z_{mainfull}, observed by the first power amplifier operating in a full power region, is given by:

$${Z}_{mainfull} = \frac{{Z}_{om} \cdot {Z}_{op}}{{Z}_{o}}$$

where Zₒₘ is the first transmission line impedance, Zₒₚ is the second transmission line impedance, and Zₒ is a load impedance driven by the power amplifier system. In some embodiments, a third impedance, Z_{peakfull}, observed by the second power amplifier operating in a full power region, is given by:

$${Z}_{peakfull} = {Z}_{mainfull} [ \frac{{Z}_{mainfull}}{{Z}_{mainback}} - 1 ]$$

where Z_{mainfull} is an impedance seen by the first power amplifier operating in a full power region and Z_{mainback} is an impedance observed by the first power amplifier operating in a backoff power region. In some embodiments, the coupling mechanism is a 3 dB hybrid coupler.

According to another aspect, the invention provides a method of simultaneously matching a main power amplifier of a Doherty power amplifier system and a peak power amplifier of the Doherty power amplifier system to a 3 dB hybrid coupler, where the main power amplifier has a first output, the peak power amplifier has a second output, and the 3 dB hybrid coupler has a first input port and a second input port. The method includes choosing a first impedance of a first transmission line and choosing a second impedance of a second transmission line. The first and second impedances are chosen to achieve the matching between the main and peak power amplifiers to the 3 dB hybrid coupler. The first transmission line having the first impedance is situated to connect the first output of the main power amplifier to the first input of the 3 dB coupler. The second transmission line having the second impedance is situated to connect the second output of the peak power amplifier to the second input port of the 3 dB coupler.

According to this aspect, in some embodiments, the first and second transmission lines are quarter wavelength transmission lines at a center frequency of operation of the Doherty power amplifier system. In some embodiments, the first and second impedances are further chosen so that impedances observed by the main power amplifier and the peak power amplifier are independent of an impedance of the 3 dB coupler. In some embodiments, the first and second impedances are further chosen so that a ratio of an impedance observed by the peak power amplifier operating in a full power region to an impedance observed by the main amplifier operating in a full power region is equal to a ratio of a peak power of the peak power amplifier to a peak power of the main power amplifier.

According to yet another aspect, the invention provides an amplifier system having a coupler, a main amplifier, and a peak amplifier. The coupler has a first input port, a second input port and an output port. The main amplifier has a first output and a first output power rating. The peak amplifier has a second output and a second output power rating. The amplifier system also has a combiner output network. The output network includes a first impedance coupling the first output of the main amplifier to the first input port of the coupler. The second impedance of the output network couples an output of the peak amplifier to the second input port of the coupler. A load impedance is connected to the first output port of the coupler. The first impedance and the second impedance are chosen based on a ratio of the second output power rating to the first output power rating.

According to this aspect, the first and second impedances are chosen so that an impedance observed by the main power amplifier and an impedance observed by the peak power amplifier are independent of an impedance of the coupler. In another embodiment, the coupler couples one half of energy received by the second input port of the coupler to the first output port of the coupler. In some embodiments, an impedance observed by the main power amplifier operating in a back off region is independent of the second impedance. In some embodiments, an impedance observed by the peak power amplifier operating in a full power region is a function of an impedance observed by the main power amplifier operating in a full power region and of an impedance observed by the main power amplifier operating in a back off power region.

According to another aspect, the invention provides a three-way Doherty power amplifier system. The three-way Doherty power amplifier system has a main power amplifier, a first peak power amplifier and a second peak power amplifier. The main power amplifier has a main power amplifier output. The first peak power amplifier has a first peak power amplifier output. The second peak power amplifier has a second peak power amplifier output. The three-way Doherty power amplifier system also has a first coupler having a first coupler first input port, a first coupler second input port and a first coupler output port coupled to a load impedance. The three-way Doherty power amplifier system also has a second coupler having a second coupler first input port, a second coupler second input port and a second coupler output port coupled to the first coupler first input port. The three-way Doherty power amplifier system also has a first impedance connecting the main power amplifier output to the first coupler second input port, a second impedance connecting the first peak power amplifier output to the second coupler first input port, and a third input impedance connecting the second peak power amplifier output to the second coupler second input port. The first, second and third impedances are chosen based on a difference in output powers of the main power amplifier and the first and second peak power amplifiers so that an impedance observed by the main power amplifier is independent of an impedance of the first coupler and impedances observed by the first and second peak power amplifiers are independent of an impedance of the second coupler.

According to this aspect, in impedance observed by the main power amplifier operating in a backoff power region may be independent of the second and third impedances and independent of impedances of the first and second coupler.

### BRIEF DESCRIPTION OF THE DRAWINGS

FIG. 1 is a known Doherty amplifier utilizing T junction output circuitry;

FIG. 2 is a graph of current and efficiency for a known Doherty amplifier;

FIG. 3 is a known Doherty amplifier using a hybrid coupler in the output circuit;

FIG. 4 is a known 3 dB hybrid coupler;

FIG. 5 is a block diagram of an exemplary Doherty amplifier with quarter length transmission lines and a 3 dB hybrid coupler constructed in accordance with principles of the present invention;

FIG. 6 is a plot of impedances seen by the main and peak amplifiers of the Doherty amplifier of FIG. 4 at full power;

FIG. 7 is a plot of the impedance seen by the main amplifier of the Doherty amplifier of FIG. 5 at backoff power;

FIG. 8 is a plot of the impedances seen by the main and peak amplifiers of a Doherty amplifier having a power ratio of 1.8 at full power;

FIG. 9 is a plot of the impedances seen by the main and peak amplifiers of the Doherty amplifier having a power ratio of 1.8 at backoff power; and

FIG. 10 is a block diagram of an exemplary three-way Doherty amplifier constructed in accordance with principles of the present invention.

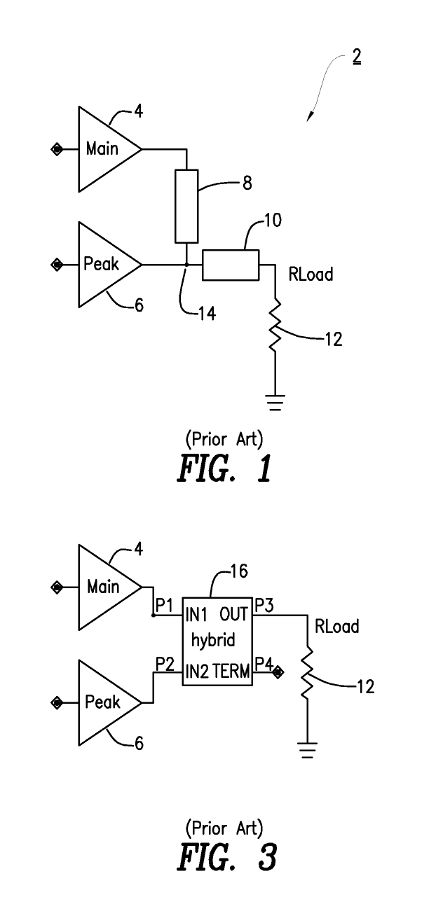

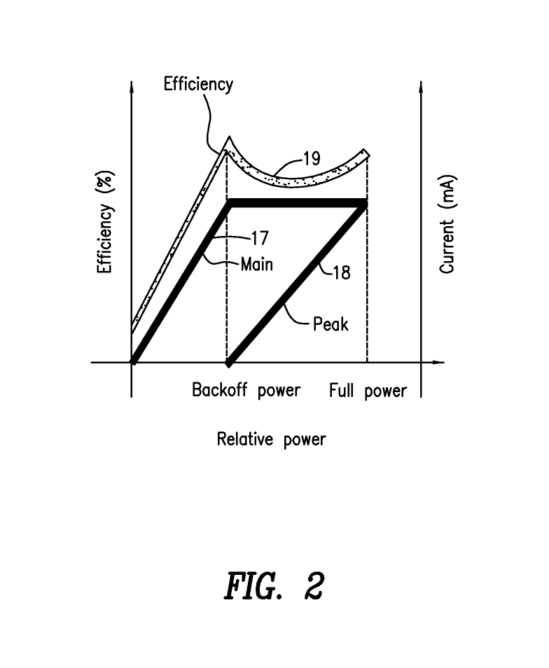

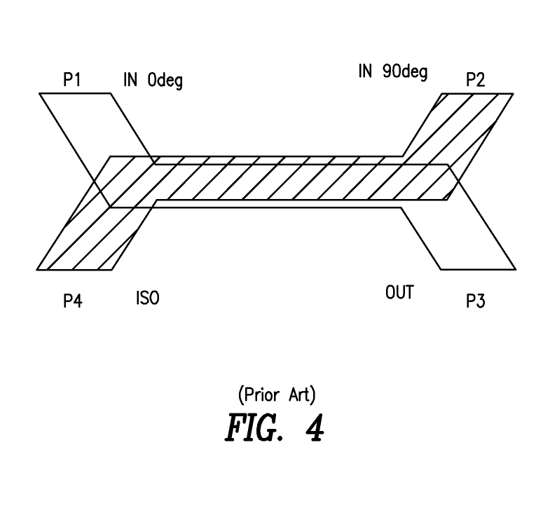

### DETAILED DESCRIPTION

Before describing in detail exemplary embodiments that are in accordance with the present invention, it is noted that the embodiments reside primarily in combinations of apparatus components and processing steps related to the design of output circuitry of a Doherty amplifier for wideband applications. Accordingly, the system and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements.

Embodiments described herein illustrate symmetric and asymmetric Doherty power amplifiers implemented using standard 3 dB hybrid couplers, branch line hybrids, lumped elements or transformers as combiners to provide broadband performance. In embodiments described herein, the impedance presented to the main and peak amplifiers are low compared to impedances presented by a T junction, for example, which makes the output circuitry easier to match.

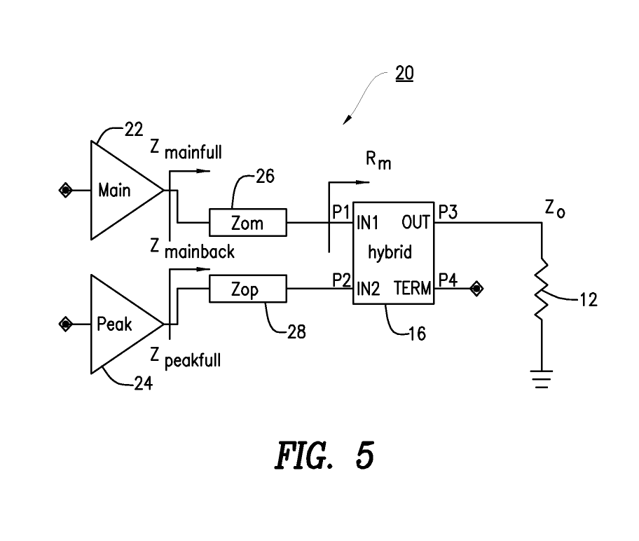

Referring now to the drawing figures in which like reference designators are used to denote like elements, there is shown in FIG. 5 a Doherty power amplifier 20, having a main power amplifier 22, a peak power amplifier 24, and a standard 3 dB hybrid coupler 16 as a combiner. The amplifiers 22 and 24 are electrically coupled to the hybrid coupler 16 by way of 2 transmission lines 26 and 28.

The impedance, Rₘ, seen looking into the hybrid coupler 16 toward the load 12 is a function of a ratio of the current, Iₚ, of the peak amplifier 24 to the current, Iₘ, of the main amplifier 22, as defined by the following equation:

$${R}_{m} = ( 2 - \frac{{I}_{p}}{{I}_{m}} ) \cdot {Z}_{o}$$

$${R}_{m} = ( 2 - m ) \cdot {Z}_{o}$$

where Zₒ is the load impedance 12. Because the hybrid coupler 16 has an equal power split, the ratio, m, is equal to 0 at backoff power and is equal to 1 at full power. The impedance, Z_{mainback}, seen by the main power amplifier 22 at backoff power is equal to:

$${Z}_{mainback} = \frac{{Z}_{om}^{2}}{{R}_{m}}$$

$${Z}_{mainback} = \frac{{Z}_{om}^{2}}{2 \cdot {Z}_{o}}$$

where Zₒₘ is the impedance of the first transmission line 26. The impedance, Z_{mainfull}, seen by the main power amplifier 22 at full power is equal to:

$${Z}_{mainfull} = \frac{{Z}_{om} \cdot {Z}_{op}}{{Z}_{m}}$$

$${Z}_{mainfull} = \frac{{Z}_{om} \cdot {Z}_{op}}{{Z}_{o}}$$

where Zₒₚ is the impedance of the second transmission line 28. Note that the impedance seen at full power and the impedance seen at backoff power are independent of the impedance of the hybrid coupler, but instead are dependent upon the impedance of the first and second transmission lines 26 and 28. The impedance, Z_{peakfull}, seen by the peak power amplifier 24 at full power is given by:

$${Z}_{peakfull} = \frac{{Z}_{mainfull}}{{Z}_{mainback}} \cdot \frac{{Z}_{opk} \cdot {Z}_{om}}{{Z}_{o}} - \frac{{Z}_{opk} \cdot {Z}_{om}}{{Z}_{o}}$$

$${Z}_{peakfull} = {Z}_{mainfull} [ \frac{{Z}_{mainfull}}{{Z}_{mainback}} - 1 ]$$

$${Z}_{peakfull} = {Z}_{mainfull} [ k - 1 ]$$

where k is the load modulation ratio of the main power amplifier 22.

Note that by interposing the quarter wave transmission lines 26 and 28 between the amplifiers 22 and 24 and the 3 dB directional coupler 16, the impedances seen by the main amplifier 22 and the peak amplifier 24 are independent of the impedance of the directional coupler 16. This means that regardless of the power ratings of the main amplifier 22 and the peak amplifier 24, a standard “off the shelf” 3 dB hybrid coupler may be employed. Thus, a specially designed coupler to match the asymmetry of the power amplifiers is not needed for use in the Doherty power amplifier 20.

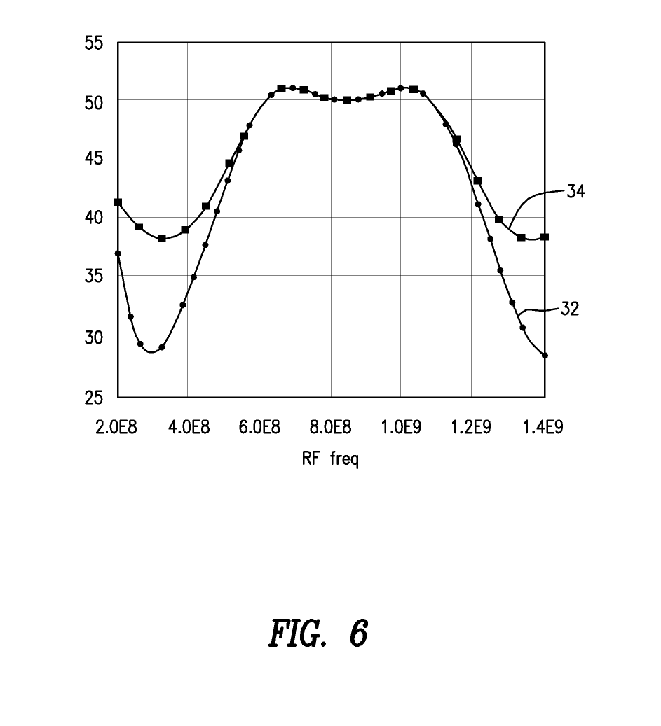

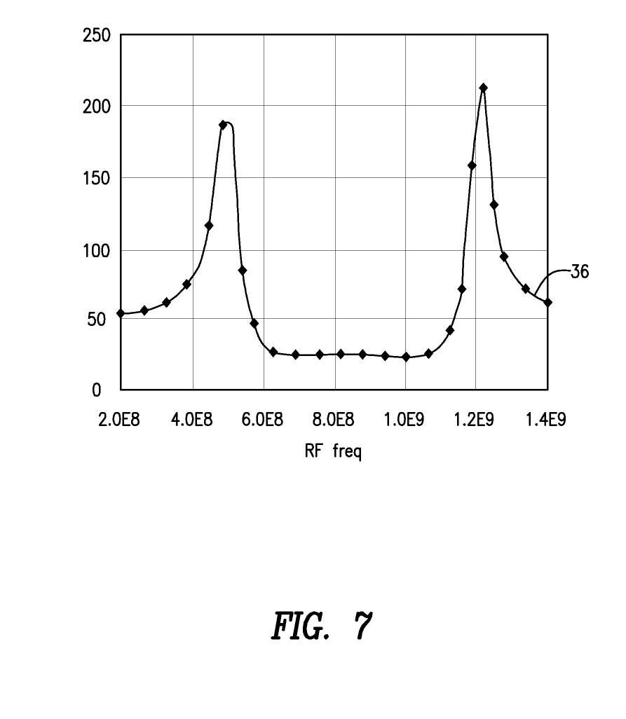

FIG. 6 is a graph of Z_{peakfull} 32 and Z_{mainfull} 34. The graph shows that the impedances presented to the main power amplifier 22 and the peak power amplifier at full power, when both transmission lines 26 and 28 are 50 ohms and the load impedance is 50 ohms, is about 50 ohms over a broad frequency range. Thus, choosing a low impedance of 50 ohms for the transmission lines 26 and 28 presents a low impedance of about 50 ohms to the main amplifier 22 and the peak amplifier 24. This is beneficial since the amplifiers of a Doherty amplifier are typically selected to match an output impedance of 50 ohms. FIG. 7 is a graph of Z_{mainback} 36 showing that the impedance presented to the main power amplifier 22 at backoff power is about 25 ohms. This is also known as an inverted Doherty configuration.

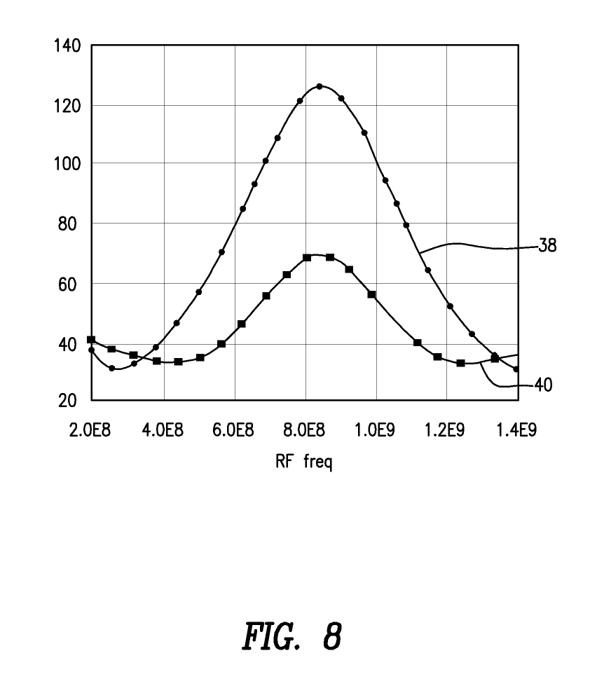

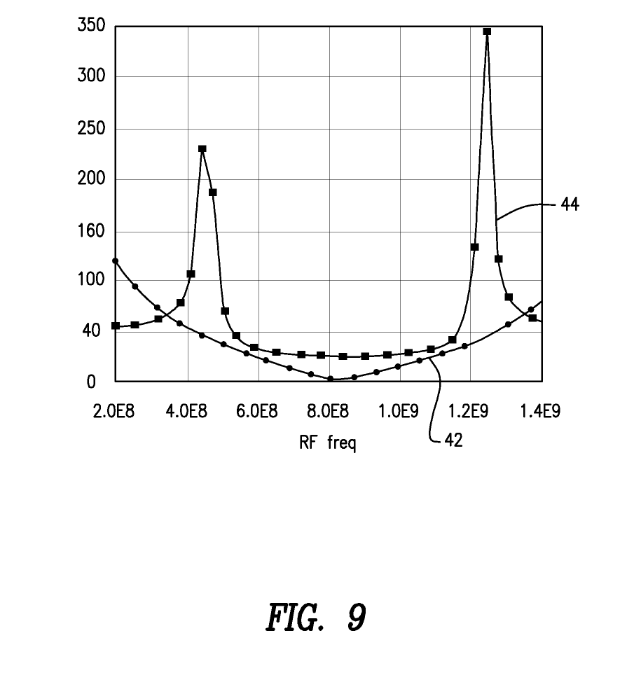

FIG. 8 is a graph of Zₚₑₐₖ 38 and Z_{mainfull} 40, when the first transmission line 26 impedance is 50 ohms, the second transmission line 28 impedance is 70 ohms, and the load impedance is 50 ohms. These values are designed for a ratio of the power rating of the peak amplifier 24 to the power rating of the main amplifier 22 of 1.8. As can be seen from FIG. 7, Zₚₑₐₖ 38 is 126 ohms at full power, and Z_{mainfull} 40 is 70 ohms at full power. FIG. 9 is a graph of the impedances at backoff power, where Zₚₑₐₖ 42 is small and reaches zero at the center frequency, and Z_{mainback} 44 is 25 ohms over a wide bandwidth. The load impedance in this case is 50 ohms. Once again, presentation of the quarter wave length transmission lines 26 and 28 results in impedances seen by the amplifiers 22 and 24 that are independent of the impedance of the coupler 16. Thus, a standard 3 dB coupler may be used notwithstanding the difference in power ratings of the amplifiers 22 and 24. Further, the impedances presented to the amplifiers 22 and 24 are low, resulting in a broader matching as compared to matching to a standard 50 ohm impedance.

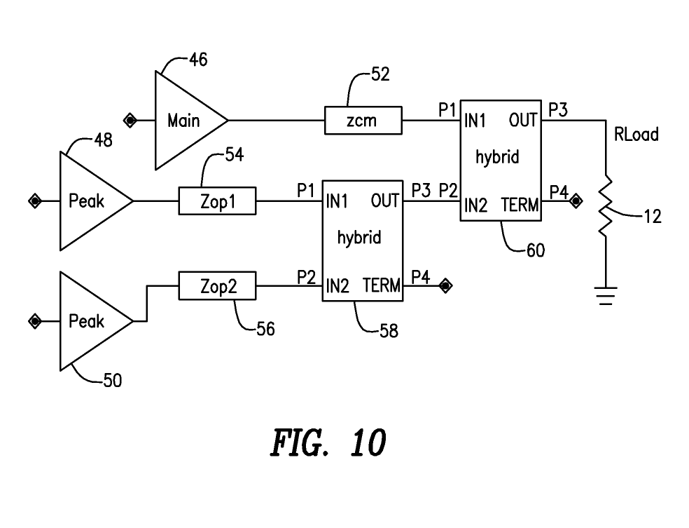

FIG. 10 shows an arrangement of an exemplary a three-way Doherty power amplifier 62, including a main amplifier 46, a first peak amplifier 48 and a second peak amplifier 50. In this embodiment, the output of the main power amplifier 46 is electrically connected to a first quarter wavelength transmission line 52. The output of the first peak amplifier 48 is electrically connected to a second quarter wavelength transmission line 54. The output of the second peak amplifier 50 is electrically connected to a third quarter wavelength transmission line 56. The second quarter wavelength transmission line 54 is electrically connected to a first input port of a hybrid coupler 58. The third quarter wavelength transmission line 56 is electrically connected to the other input port of the hybrid coupler 58. A first output of the hybrid coupler 58 is electrically connected to a first input of a hybrid coupler 60. The second output of the hybrid coupler 58 may be an open or a short. The first quarter wavelength transmission line 52 is electrically connected to the other input of the hybrid coupler 60. A first output of the hybrid coupler 60 is electrically connected to the load impedance 12. The second output of the hybrid coupler 60 may be an open or a short.

To design the circuitry of FIG. 10, the first, second and third impedances 52, 54 and 56 are chosen based on a difference in output power ratings of the main power amplifier 46 and the first and second peak power amplifiers 48 and 50 so that an impedance observed by the main power amplifier 46 is independent of the impedance of the coupler 60 and impedances observed by the first and second peak power amplifiers are independent of the impedance of the coupler 58. Because the impedances seen by the power amplifiers 46, 48 and 50 are independent of the couplers 58 and 60, standard 3 dB couplers may be employed, regardless of a difference in the power ratings of the amplifiers 46, 48 and 50. Enabling use of standard 3 dB couplers avoids the cost and board space that would be incurred if specially designed couplers were required, as in the prior art. The concepts discussed herein can be applied to an N-way Doherty amplifier where N is an integer greater than 1.

Embodiments described herein achieve wideband performance using a standard surface mounted hybrid combiner that does not need to be specially designed even when the power ratings of the different amplifiers of the Doherty amplifier system are not the same.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A power amplifier system, comprising:
a first power amplifier having a first power amplifier output;
a second power amplifier having a second power amplifier output;
a first quarter wave transmission line having an input connected to the first power amplifier output of the first power amplifier, the first quarter wave transmission line having a first transmission line output and a first transmission line impedance;
a second quarter wave transmission line having an input connected to the second power amplifier output of the second power amplifier, the second quarter wave transmission line having a second transmission line output and having a second transmission line impedance;
a symmetric coupling mechanism having:
a coupling mechanism impedance;
a first input connected to the first transmission line output of the first quarter wave transmission line; and
a second input connected to the second transmission line output of the second quarter wave transmission line;
the first and second transmission line impedances chosen based on a ratio of power ratings of the first power amplifier and the second power amplifier.

2. The power amplifier system of claim 1, wherein a third impedance observed by the first power amplifier is independent of the coupling mechanism impedance.

3. The power amplifier system of claim 1, wherein a third impedance observed by the second power amplifier is independent of the coupling mechanism impedance.

4. The power amplifier system of claim 1, wherein the coupling mechanism impedance is a function of a ratio of a current in the second transmission line to a current in the first transmission line.

5. The power amplifier system of claim 1, wherein the coupling mechanism impedance, Rₘ, is given by:
$${R}_{m} = ( 2 - \frac{{I}_{p}}{{I}_{m}} ) \cdot {Z}_{o}$$
where Iₚ is a current in the second amplifier, Iₘ is a current in the first amplifier, and Zₒ is a load impedance driven by the power amplifier system.

6. The power amplifier system of claim 1, wherein a third impedance, Z_{mainback}, observed by the first power amplifier operating in a backoff power region, is given by:
$${Z}_{mainback} = \frac{{Z}_{om}^{2}}{2 \cdot {Z}_{o}}$$
where Zₒₘ is the first transmission line impedance and Zₒ is a load impedance driven by the power amplifier system.

7. The power amplifier system of claim 1, wherein a third impedance, Z_{mainfull}, observed by the first power amplifier operating in a full power region, is given by:
$${Z}_{mainfull} = \frac{{Z}_{om} \cdot {Z}_{op}}{{Z}_{o}}$$
where Zₒₘ is the first transmission line impedance, Zₒₚ is the second transmission line impedance, and Zₒ is a load impedance driven by the power amplifier system.

8. The power amplifier system of claim 1, wherein a third impedance, Z_{peakfull}, observed by the second power amplifier operating in a full power region, is given by:
$${Z}_{peakfull} = {Z}_{mainfull} [ \frac{{Z}_{mainfull}}{{Z}_{mainback}} - 1 ]$$
where Z_{mainfull} is an impedance seen by the first power amplifier operating in a full power region and Z_{mainback} is an impedance observed by the first power amplifier operating in a backoff power region.

9. The power amplifier system of claim 1, wherein the coupling mechanism is a 3 dB hybrid coupler.

10. A method of simultaneously matching a main power amplifier of a Doherty power amplifier system and a peak power amplifier of the Doherty power amplifier system to a 3 dB hybrid coupler, the main power amplifier having a first output, the peak power amplifier having a second output, the 3 dB hybrid coupler having a first input port and a second input port, the method comprising:
choosing a first impedance of a first transmission line;
choosing a second impedance of a second transmission line, the first and second impedances chosen to achieve the matching between the main and peak power amplifiers to the 3 dB hybrid coupler;
situating the first transmission line having the first impedance to connect the first output of the main power amplifier to the first input port of the 3 dB coupler; and
situating the second transmission line having the second impedance to connect the second output of the peak power amplifier to the second input port of the 3 dB coupler.

11. The method of claim 10, wherein the first and second transmission lines are quarter-wave transmission lines at a center frequency of operation of the Doherty power amplifier system.

12. The method of claim 10, wherein the first and second impedances are further chosen so that impedances observed by the main power amplifier and the peak power amplifier are independent of an impedance of the 3 dB coupler.

13. The method of claim 10, wherein the first and second impedances are further chosen so that a ratio of an impedance observed by the peak power amplifier operating in a full power region to an impedance observed by the main amplifier operating in a full power region is equal to a ratio of a peak power of the peak power amplifier to a peak power of the main power amplifier.

14. An amplifier system, comprising:
a coupler having a first input port, a second input port and an output port;
a main amplifier having a first output and a first output power rating;
a peak amplifier having a second output and a second output power rating; and
an output network, comprising:
a first impedance coupling the first output of the main amplifier to the first input port of the coupler;
a second impedance coupling an output of the peak amplifier to the second input port of the coupler; and
a load impedance connected to the first output port of the coupler;
the first impedance and the second impedance chosen based on a ratio of the second output power rating to the first output power rating.

15. The amplifier system of claim 14, wherein the first and second impedances are chosen so that an impedance observed by the main power amplifier and an impedance observed by the peak power amplifier are independent of an impedance of the coupler.

16. The amplifier system of claim 14, wherein the coupler couples one half of energy received by the second input port of the coupler to the first output port of the coupler.

17. The amplifier system of claim 14, wherein an impedance observed by the main power amplifier operating in a back off region is independent of the second impedance.

18. The amplifier of claim 14, wherein an impedance observed by the peak power amplifier operating in a full power region is a function of an impedance observed by the main power amplifier operating in a full power region and of an impedance observed by the main power amplifier operating in a back off power region.

19. A 3-way Doherty power amplifier system, comprising:
a main power amplifier having a main power amplifier output;
a first peak power amplifier having a first peak power amplifier output;
a second peak power amplifier having a second peak power amplifier output;
a first coupler having a first coupler first input port, a first coupler second input port and a first coupler output port coupled to a load impedance;
a second coupler having a second coupler first input port, a second coupler second input port and a second coupler output port coupled to the first coupler first input port;
a first impedance connecting the main power amplifier output to the first coupler second input port;
a second impedance connecting the first peak power amplifier output to the second coupler first input port;
a third impedance connecting the second peak power amplifier output to the second coupler second input port;
the first, second and third impedances chosen based on a difference in output powers of the main power amplifier and the first and second peak power amplifiers so that an impedance observed by the main power amplifier is independent of an impedance of the first coupler and impedances observed by the first and second peak power amplifiers are independent of an impedance of the second coupler.

20. The 3-way Doherty power amplifier system of claim 19, wherein an impedance observed by the main power amplifier operating in a back off power region is independent of the second and third impedances and is independent of impedances of the first and second coupler.
